(19) United States
(12) Patent Application Publication
(10) Pub. No.: US 2009/0067483 A1
(43) Pub. Date: Mar. 12, 2009

(54) Efficient adaptive equalizer implementation

(76) Inventors: Raul Casas, Doylestown, PA (US); Stephen Leonard Biracree, Rochester, NY (US); Slobodan Simovich, San Francisco, CA (US); Thomas Joseph Endres, Seattle, WA (US)

Correspondence Address: OLYMPIC PATENT WORKS PLLC, P.O. BOX 4277, SEATTLE, WA, 98104, US

(21) Appl. No.: 12/229,726

(22) Filed: Aug. 26, 2008

Related U.S. Application Data
(60) Provisional application No. 60/966,620, filed on Aug. 29, 2007.

(51) Int. Cl. H03K 5/159

(52) U.S. Cl. 375/232

(57) ABSTRACT

The present invention is related to the digital implementation of adaptive equalizers for high-speed communication systems, using finite precision arithmetic, for example, as implemented in a silicon ASIC.

### CROSS REFERENCE TO RELATED APPLICATION

This application claims the benefit of Provisional Application No. 60/966,620, filed Aug. 29, 2007.

### FIELD OF INVENTION

The present invention is related to the digital implementation of adaptive equalizers for high-speed communication systems, using finite precision arithmetic, for example, as implemented in a silicon ASIC.

### BACKGROUND OF INVENTION

Equalization in a digital receiver is a process whereby multipath, noise, and other interferences incurred in the digital broadcast are removed from the received signal, attempting to restore the original digital transmission. Since the characteristics of the broadcast channel are rarely known a priori to the receiver, and can change dynamically, equalizers are usually implemented using adaptive filters.

Most state-of-the-art digital receivers use some type of decision feedback equalizer (DFE), because it provides superior inter-symbol interference (ISI) cancellation with less noise gain than a finite impulse response (FIR)-only equalizer structure. Austin first proposed a DFE, in a report entitled “Decision feedback equalization for digital communication over dispersive channels,” MIT Lincoln Labs Technical Report No. 437, Lexington, Mass., August 1967. A DFE acts to additively cancel ISI by subtracting filtered symbol estimates from the received waveform. The feedback structure embeds a FIR filter in a feedback loop, and therefore overall has an infinite impulse response (IIR). Most modern DFE's use two adaptive filters, a first linear, forward filter coupled to the feedback structure which embeds a second, feedback filter.

For communication systems broadcasting through a channel medium with a long delay spread relative to the symbol period, the adaptive filters in the equalizer must be long enough to cover the channel delay spread, resulting in a significant number of equalizer coefficients, and implementation penalty needed to realize them. For example, digital television (DTV) broadcast in the U.S. is according to the Advanced Television Systems Committee (ATSC) standard (see ATSC Digital Television Standard (A/53) Revision E) and transmits about 10.76 million digital symbols per second through VHF/UHF, which can display delay spreads up to 100 microseconds. Hence, an ATSC receiver may have over a thousand adaptive equalizer coefficients. It is typical for such high speed receivers to have well over half their silicon real estate dedicated solely to adaptive equalizer circuitry, making the adaptive equalizer the most expensive signal processing on the chip. Implementation methods which reduce such burden are therefore desirable. The present invention relates to the efficient implementation of adaptive equalizers.

### SUMMARY OF INVENTION

The present invention is related to the efficient implementation of adaptive equalizers for high-speed communication systems, using finite precision arithmetic, for example, as implemented in a silicon ASIC.

### BRIEF DESCRIPTION OF DRAWINGS

Other aspects, features, and advantages of the present invention will become more fully apparent from the following detailed description, the appended claims, and the accompanying drawings in which:

FIG. 1 shows a typical prior art digital television broadcast communication system;

FIG. 2 shows a typical prior art digital receiver system;

FIG. 3 shows a prior art decision feedback equalizer;

FIG. 4 shows a prior art update term calculator;

FIG. 5 shows an equalizer adaptation system in accordance with the present invention;

FIG. 6 shows error term preparation circuitry in accordance with the present invention;

FIG. 7 shows equalizer adaptation circuitry in accordance with the present invention;

FIG. 8 shows error term preparation circuitry in accordance with the present invention;

FIG. 9 shows equalizer adaptation circuitry in accordance with the present invention; and

FIG. 10 shows alternative equalizer adaptation circuitry in accordance with the present invention.

### DETAILED DESCRIPTION

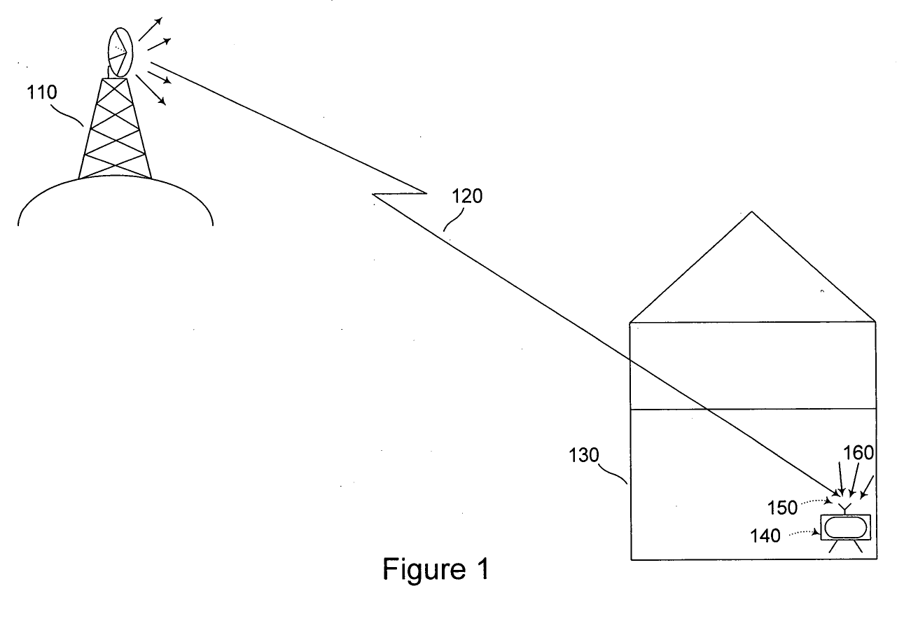

FIG. 1 depicts a typical prior art digital television broadcast communication system, used as an exemplary communication system for which the present invention is applicable. Transmitter station 110 broadcasts Digital Television (DTV) signal 120, which radiates through house 130 to antenna 150. The induced penetration loss of the RF carrier's signal power through house 130 can be significant, easily 20 dB. Antenna 150 is usually in close proximity to television 140, or can be remotely connected to television 140. Antenna 150 also receives multipath signals, collectively 160, which can be caused by reflections from other buildings, or items interior to house 130, such as walls, furniture, persons, etc. Furthermore, in most viewing environments, the television 140 is located in a communal part of house 130, so that reflections from moving persons, etc. induce time varying multipath signals 160. Any reflections from moving cars or airplanes cause further time variations in multipath signals 160.

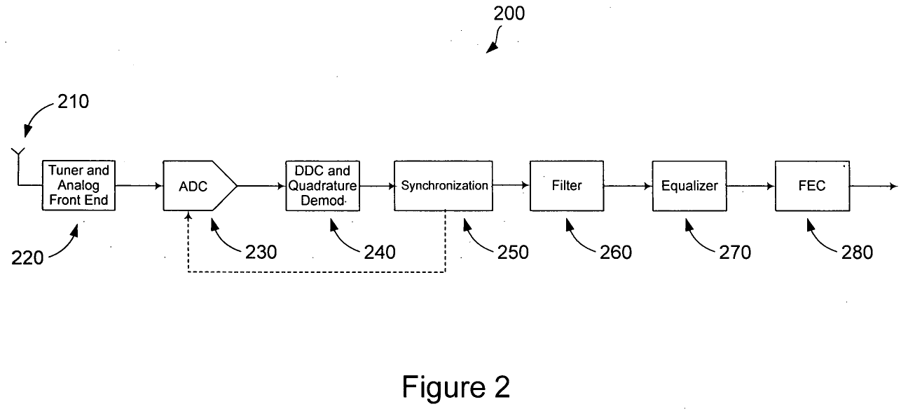

FIG. 2 shows a typical prior art digital receiver system 200. Antenna 210 receives DTV broadcast signal 120, and is coupled to Tuner and Analog Front End module 220. Tuner and Analog Front End module 220 tunes to the proper broadcast channel, performs level setting, synchronization, further frequency translation and filtering, and couples the signal to ADC 230. ADC 230 digitizes the analog signal, typically 10-12 bits for DTV, and supplies the bit stream to DDC and quadrature demodulation module 240. DDC and quadrature demodulation module 240 performs direct digital downconversion (DDC) and in-phase/quadrature-phase split into complex near-baseband. In addition, other filtering may be used, for example, rejection of adjacent broadcasts. The near-baseband signal from DDC and quadrature demodulation module 240 is coupled to synchronization module 250. Synchronization module 250 aligns the sample rate and phase of the received samples to the transmitted data samples, by known methods, typically either interpolating the data or adjusting the sample clock of ADC 230. Furthermore, carrier phase and frequency recovery may be done using the pilot tone that is embedded into the DTV data spectrum, using known methods. Timed data from synchronization module 250 is supplied to matched filter 260, which usually performs square-root raised cosine filtering that is matched to the pulse shape filter applied at the Transmitter 110. The output of matched filter 260 is supplied to equalizer 270, which performs adaptive equalization to mitigate inter-symbol interference incurred in the broadcast channel. Furthermore, equalizer 270 may include a fine carrier recovery loop, translating the data to precise baseband. Equalizer 270 provides an equalized signal to FEC 280, which performs forward error correction to minimize the received bit error rate and provides the recovered digital video signal, usually as MPEG packets, which can be decoded and viewed on a television. The present invention pertains to the equalizer 270 in the digital receiver.

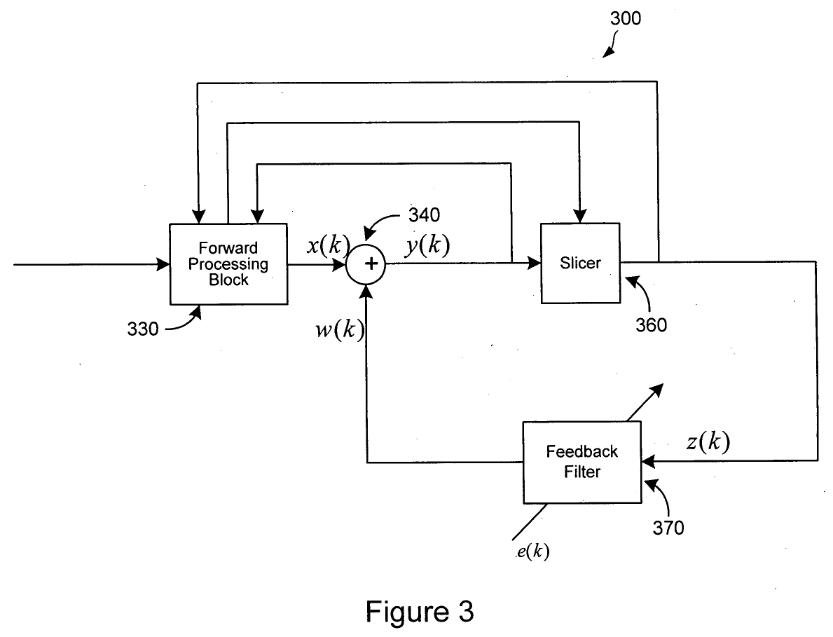

FIG. 3 depicts a block diagram of a prior art equalizer and encapsulates the equalizer architectures described in “Feasibility of reliable 8-VSB reception” by C. H. Strolle et al, Proceedings of the NAB Broadcast Engineering Conference,” Las Vegas, Nev., pp. 483-488, Apr. 8-13, 2000. The equalizer in FIG. 3 is suitable for Vestigial Sideband (VSB) signals, for example, in accordance with the ATSC DTV broadcast standard. The equalizer in FIG. 3 is also suitable for QAM signals, encapsulating the equalizer architecture described in “Carrier independent blind initialization of a DFE,” by T. J. Endres et al., in Proceedings of the IEEE Workshop on Signal Processing Advances in Wireless Communications, Annapolis, Md., May 1999. One skilled in the art would know how to use the equalizer architecture described in FIG. 3 for a variety of signal formats commonly used in digital communication systems.

Forward processing block 330 encompasses multiple prior art signal processing functions, and may include circuitry for adaptive forward filtering, carrier recovery, error term generation, et al., for example. See “Phase detector in a carrier recovery network for a vestigial sideband signal,” U.S. Pat. No. 5,706,057 issued Jan. 6, 1998, by C. H. Strolle et al., for carrier recovery techniques suitable to VSB signals. For QAM signals, decision-directed carrier estimation techniques are described in Chapter 16 of Digital Communication—Second Edition, Lee and Messerschmitt, Kluwer Academic Publishers, Boston, Mass., 1997. See Theory and Design of Adaptive Filters, New York, John Wiley and Sons, 1987, by Treichler et al for a description of adaptive filters, including forward adaptive filtering and error term generation.

Forward processing block 330 receives input samples from front end signal processing blocks of the digital receiver, for example, as shown in FIG. 2. Forward processing block 330 also receives soft decision sample y(k) input to slicer 360, and also receives output of slicer 360. Forward processing block 330 further may provide output to slicer 360, for example to provide sine and cosine terms to slicer 360 if slicer 360 is to form passband samples, as described in “Carrier independent blind initialization of a DFE,” by T. J. Endres et al., in Proceedings of the IEEE Workshop on Signal Processing Advances in Wireless Communications, Annapolis, Md., May 1999.

Adder 340 sums x(k) with feedback filter 370 output w(k) to provide sample y(k), referred to as the soft-decision sample. Soft decision sample y(k) is provided to slicer 360. Slicer 360 produces a symbol estimate (also referred to as a hard decision sample). Slicer 360 can be a nearest-element decision device, selecting the source symbol with minimum Euclidean distance to the soft decision sample, or can take advantage of the channel coding. For example, a partial trellis decoder is used as slicer 360 in “A method of estimating trellis encoded symbols utilizing simplified trellis decoding,” U.S. Pat. No. 6,178,209, issued Jan. 23, 2001, by S. N. Hulyalkar et al. Slicer 360 may also receive an input signal from forward processing block 330, for example, including sine and cosine terms which may be used for rotation and de-rotation in accordance with previously cited prior art techniques.

The output from slicer 360 is used to form regressor sample z(k) for feedback filter 370. Feedback filter 370 receives regressor samples z(k) and produces output sample w(k) to adder 340. Feedback filter 370 is usually implemented with adaptive coefficients, and is therefore provided error term e(n) for coefficient adjustment. Error term e(n) may be generated in forward processing block 330 or elsewhere in the receiver architecture.

The adaptive filter contained in forward processing block 330 and feedback filter 370 may be comprised of real- or complex-valued coefficients, may process real- or complex-valued data, and may adjust coefficients or blocks of coefficients using real- or complex-valued error.

For an adaptive filter updated with a stochastic gradient descent rule, the adaptation process can generally be written as

\vec{ƒ}ₙ₊₁=\vec{ƒ}ₙ− [symbol] \vec{ƒ}ₙ>>ρ [symbol] − [symbol] \vec{r}_{n-∂}*·e_{n-∂}>>μ

[symbol]

where \vec{ƒ} is a vector of adaptive filter coefficients, μ is the stepsize (assumed time-invariant for simplicity), \vec{r}ₙ* is the conjugated regressor vector of inputs to the adaptive filter, eₙ is an adaptive error term, and ρ is a leakage term. We immediately assume that both the stepsize and leakage will be implemented with a shift, instead of a pure multiplier, and are denoted by >> operator to mean a shift down by the designated number of bits. Delay ∂ is ideally zero, though a small number is usually tolerable to ease timing constraints for implementation.

The stochastic gradient descent update style is perhaps the most commonly implemented adaptive filter architecture, due to its relatively low computational burden. For a succinct but thorough study of this and other adaptive filter theories, see Theory and Design of Adaptive Filters, New York, John Wiley and Sons, 1987, by Treichler et al. See this reference also for descriptions of common adaptive error terms such as the Least Mean Squares algorithm (LMS) and Constant Modulus Algorithm (CMA), as well as for a study of leakage and stepsize selection.

For full-complex arithmetic, i.e., the regressor data in the filter's tapped delay line, the error terms used to update the filter coefficients, and the filter coefficients themselves are all complex-valued, the above update equation for the filter coefficients is split into complex components, and the equation can be re-written as

\vec{ƒ}ₙ₊₁^{l}=\vec{ƒ}ₙ^{l}− [symbol] \vec{ƒ}ₙ^{l}>>ρ [symbol] − [symbol] (\vec{r}_{n-∂}^{l}·e_{n-∂}^{l})+(\vec{r}_{n-∂}^{Q}·e_{n-∂}^{Q}))>>μ

[symbol]

\vec{ƒ}ₙ₊₁^{Q}=\vec{ƒ}ₙ^{Q}− [symbol] \vec{ƒ}ₙ^{Q}>>ρ [symbol] − [symbol] ((\vec{r}_{n-∂}^{l}·e_{n-∂}^{Q})−(\vec{r}_{n-∂}^{Q}·e_{n-∂}^{l}))>>μ

[symbol]

where (·)^{l} denotes in-phase component and (·)^{Q} denotes quadrature-phase component.

By separating into in-phase and quadrature-phase components, it is clear that four multipliers and two additions are needed for the inner product of regressor data and error term, which must necessarily be calculated separately for each adaptive filter coefficient. Even with resource sharing possible due to over-clocking, the number of multiplies and adds required for this adaptation still stands as a major contributor to silicon area.

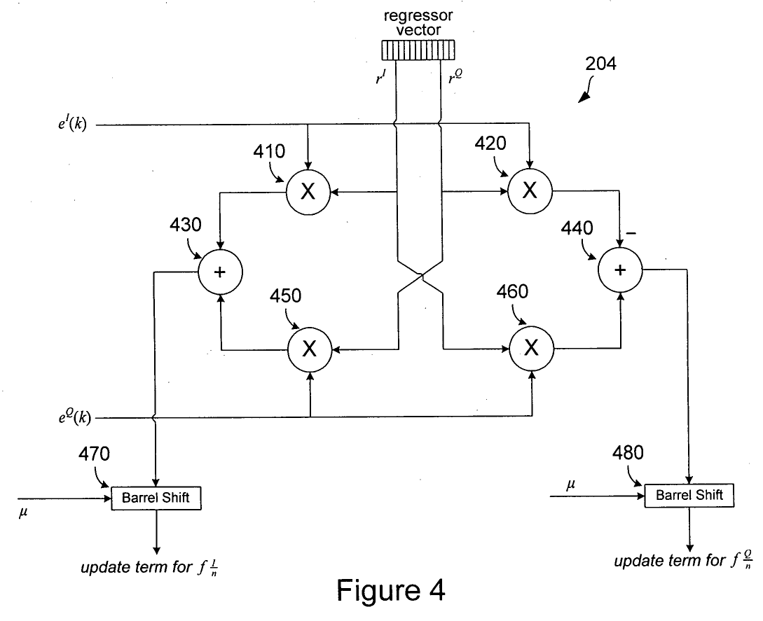

FIG. 4 shows a prior art circuit to calculate the update terms for the adaptive coefficients, that is, the inner products of regressor data and error term with stepsize applied, to illustrate the number of multiplies and adders needed. Adder 430 sums the result of multiplier 410 and multiplier 450, which form the products of in-phase regressor data and in-phase error term, and quadrature-phase regressor data and quadrature-phase error term, respectively. The stepsize μ is applied to the output of adder 430 in barrel shift 470 to form the update term for the in-phase adaptive filter coefficient.

Analogously for the quadrature phase side, adder 440 subtracts the result of multiplier 420 from the result of multiplier 460, which form the products of quadrature-phase regressor data and in-phase error term, and in-phase regressor data and quadrature-phase error term, respectively. The stepsize μ is applied to the output of adder 440 in barrel shift 480 to form the update term for the quadrature-phase adaptive filter coefficient.

Observe that four multipliers and two adders are needed to form the update terms according to this standard prior art technique.

After some algebraic manipulations, however, the adaptation equations can be re-written as

\vec{ƒ}ₙ₊₁^{l}=\vec{ƒ}ₙ^{l}− [symbol] \vec{ƒ}ₙ^{l}>>ρ [symbol] − [symbol] ((\vec{r}_{n-∂}^{l}+\vec{r}_{n-∂}^{Q})·e_{n-∂}^{l}+\vec{r}_{n-∂}^{Q}·(e_{n-∂}^{Q}−e_{n-∂}^{l}))>>μ

[symbol]

\vec{ƒ}ₙ₊₁^{Q}=\vec{ƒ}ₙ^{Q}− [symbol] \vec{ƒ}ₙ^{Q}>>ρ [symbol] − [symbol] (−(\vec{r}_{n-∂}^{l}+\vec{r}_{n-∂}^{Q})·e_{n-∂}^{l}+\vec{r}_{n-∂}^{l}·(e_{n-∂}^{Q}−e_{n-∂}^{l}))>>μ

[symbol]

In these equations, the number of multiplies needed for the update term (inner product of regressor data and error term) is reduced from four to three, at the expense of one additional adder, for each adaptive filter coefficient—observe that the product of in-phase error term with sum of in-phase and quadrature-phase components of regressor data is common to both equations. Since a multiplier requires more silicon area than an adder, there is a potential for significant implementation savings. Sum and differences of error terms are used, rather than just the error terms themselves, and are calculated common to all equalizer coefficients.

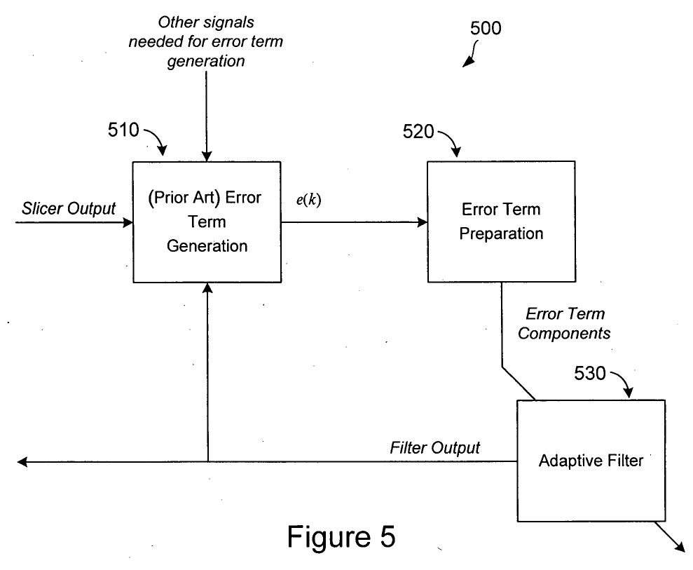

FIG. 5 illustrates an equalizer adaptation system 500 used to update adaptive filter coefficients, in accordance with the present invention. An error term e(k) is formed in error term generation module 510 using prior art techniques, for example, CMA, LMS, or any other error update style. To form the error term, error term generation module 500 receives signals from a slicer, the output of the adaptive filter 530, and possibly other signals needed to form the error term according to prior art techniques. The complex-valued error term from error term generation module 510 is provided to error term preparation module 520, which forms the required sum and difference error terms (or error term components) needed to implement the reduced-complexity adaptation equations in accordance with the present invention. The error term components from error term preparation module 520 are provided to adaptive filter 530 and used to adjust the coefficients of the adaptive filter 530.

To illustrate the implementation of these reduced-complexity equations as for a silicon ASIC, the following finite-precision notation is adopted. A signal is represented in two's complement notation by <m,n,s> where m is the total number of bits used to represent the signal, n is the number of integer bits, and s=0 denotes an unsigned number, while s=1 denotes a signed number. As an example, consider a signal represented as <6,2,1>, which can be written as

s2^{l}2⁰·2⁻¹2⁻²2⁻³=sxx·xxx

and has a range of values from −4 to +(4−2⁻³).

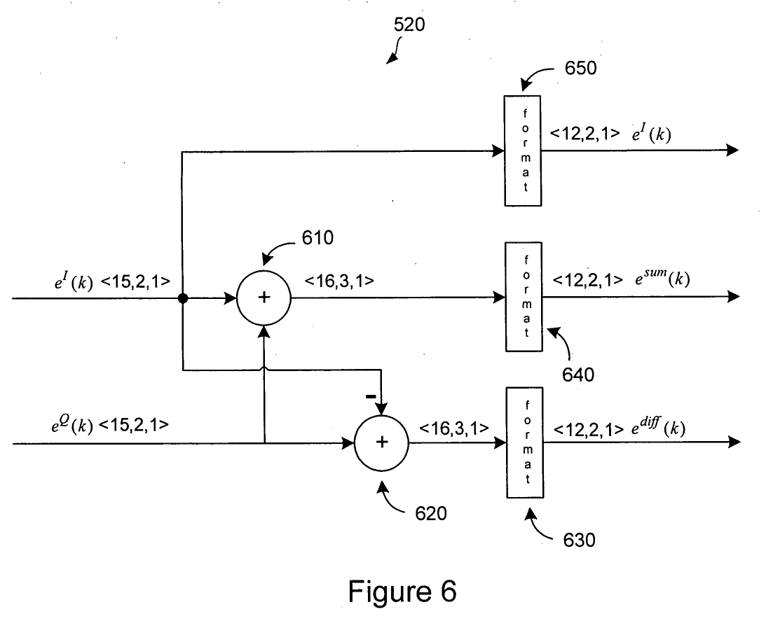

FIG. 6 shows error term preparation module 520, which receives complex-valued error term e(k)=e^{l}(k)+j·e^{Q}(k) from error term generation module 510. The complex-valued error term is here represented as <15,2,1>, suitable to a constellation with integer values, ±{1,3,5,7}. Adder 610 forms the sum of the in-phase and quadrature-phase components of the error term, and format block 640 truncates the sum to <12,2,1> and forms signal e^{sum}(k). Adder 620 forms the difference between quadrature-phase and in-phase components of the error term, and format block 630 truncates the difference to <12,2,1> and forms signal e^{diff}(k). Format block 650 truncates the in-phase component of the error term to <12,2,1> and renames the signal e^{l}(k). Signals e^{sum}(k), e^{diff}(k), and e^{l}(k), collectively called error term components, are used to adapt the equalizer coefficients in accordance with the present invention. These terms are common to all equalizer coefficients.

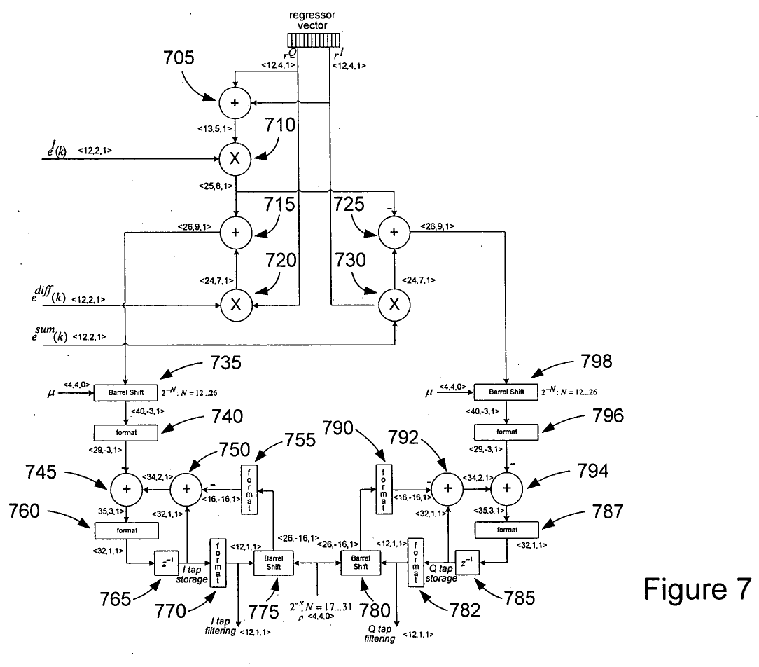

FIG. 7 illustrates equalizer adaptation circuitry 700 suitable for adjustment of complex-valued coefficients, in accordance with the present invention. Adder 705 sums the in-phase and quadrature-phase components of the regressor data, represented as <12,4,1>, suitable to a constellation with integer values, ±{1,3,5,7}, and produces a <13,5,1> result which is multiplied by e^{l}(k) from error term preparation module 520 in multiplier 710 to produce a <25,8,1> result. Multiplier 720 multiplies the quadrature part of the regressor sample with the difference error e^{diff}(k) from error term preparation module 520 and the result is added to the <25,8,1> output of multiplier 710 in adder 715, producing the <26,9,1> value that will be operated on by stepsize and leakage and used to update the in-phase component of the complex-valued adaptive coefficient.

Multiplier 730 multiplies the in-phase part of the regressor sample with the sum error e^{sum}(k) from error term preparation module 520 and the result is added to the <25,8,1> output of multiplier 710 in adder 725, producing the <26,9,1> value that will be operated on by stepsize and leakage and used to update the quadrature-phase component of the complex-valued adaptive coefficient.

The update of the in-phase component of the complex-valued coefficient is next described; update of the quadrature-phase component is analogous, based on the output of adder 725 instead of adder 715. The <26,9,1> output of adder 715 is shifted down by an integer number of bits in barrel shift 735 according to the stepsize value μ. The stepsize value μ is an unsigned integer between 0 and 15, represented as <4,4,0>, and assigns a shift value of (μ+11) to barrel shift 735 for nonzero μ, thus accomplishing the shift range of 12 to 26. If μ is zero, the output of barrel shift 735 is zeroed. The output of barrel shift 735 extends to <40,−3,1> to accommodate the complete shift range possible, and is truncated to <29,−3,1> in format 740. This <29,−3,1> output of format 740 is applied to the adder 745 which produces the updated coefficient.

In this adaptation circuitry, the coefficients are updated and stored at a higher precision than what is used in the filtering process of the adaptive filter; this prior art implementation detail helps save silicon area, compared to constraining the coefficient to the same bit width in filtering and adaptation processes, as studied in “Effects of finite bit precision on the constant modulus algorithm,” by L. Litwin et al., in Proceedings of the International Conference on Acoustics, Speech, and Signal Processing, Phoenix, Ariz., April, 1999.

The <35,3,1> updated coefficient produced by adder 745 is truncated to <32,1,1> in format 760 and stored in register 765. Format 770 truncates the stored coefficient to <12,1,1> and this result is used in the filtering process, and for leakage in barrel shift 775. Barrel shift 775 applies a shift value of (ρ+16) to barrel shift 775 for nonzero ρ, thus accomplishing the shift range of 17 to 31. If ρ is zero, the output of barrel shift 775 is zeroed. The output of barrel shift 775 extends to <26,−16,1> to accommodate the complete shift range possible, and is truncated to <16,−16,1> in format 755. This <16,−16,1> output of format 755 is summed with the <32,2,1> stored coefficient from register 765 in adder 750, and the <34,2,1> result is supplied to adder 745, which produces the next updated coefficient.

According to the present invention, for an adaptive filter using real-valued signal processing, the error term from error term generation module 510 is split into mantissa and exponent (e=eMant·2^{-eExp}) to reduce the multiplier sizes needed to update the adaptive filter coefficients, and the adaptation equation is written as

\vec{ƒ}ₙ₊₁=\vec{ƒ}ₙ− [symbol] \vec{ƒ}ₙ>>ρ [symbol] − [symbol] (\vec{x}_{n-∂}·eMant_{n-∂})>>(μ+eExp_{n-∂)}

[symbol]

The mantissa portion of the error term is reduced-precision compared to the error term from error term generation module 510, and the exponent portion of the error term is a shift by a power of two, so is added to the stepsize shift value, and a single barrel shift can accomplish application of stepsize and error term exponent. Thus, silicon area is saved.

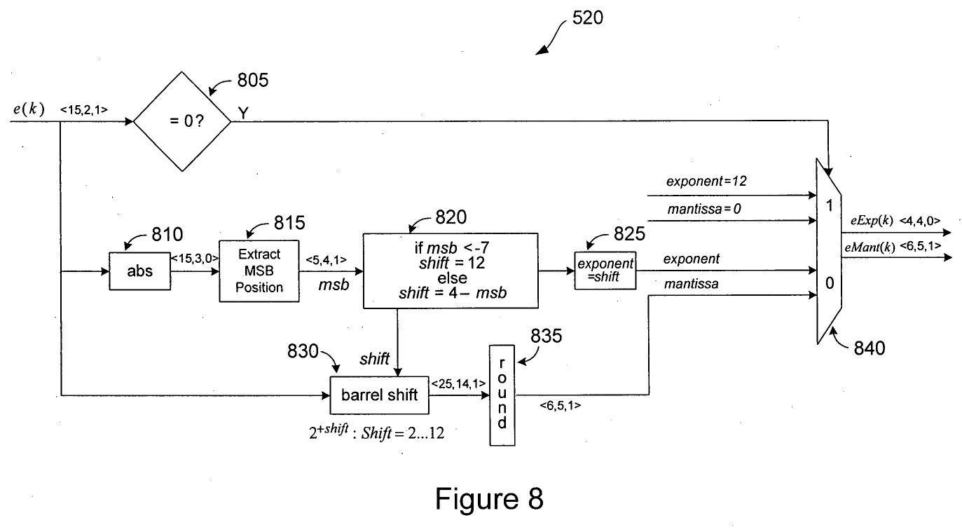

FIG. 8 illustrates an error term preparation module 520 in accordance with the present invention suitable for an equalizer adaptation system 500 used to update real-valued adaptive filter coefficients. Real-valued error term e(k) is provided from error term generation module 510. The real-valued error term is here represented as <15,2,1>, suitable to a constellation with integer values, ±{1,3,5,7}. Decision block 805 checks to see if the error term is zero, and if true, will select the “1” position of multiplexer 840. The <15,2,1> error term from error term generation module 510 is used to derive exponent and mantissa values. The exponent is derived by first taking the absolute value in abs block 510, producing a <15,3,0> result. The most significant bit (MSB) position is found in extract-MSB-position 815, and can be represented by a <5,4,1> number. In comparison block 820, the msb position reported from extract-MSB-position 815 is used to determine a shift value; if msb is less than minus seven, then the shift value is set to twelve, else the shift value is set to four minus the msb. The candidate exponent for multiplexer 840 is set to the shift value in assignment block 825. The shift value from comparison block 820 is also provided to barrel shift. 830, which shifts up the <15,2,1> error term by the shift value, in the range of 2 to 12. The output of barrel shift 830 is therefore represented by <25,14,1>, and is truncated with rounding down to <6,5,1> in round block 835 to form candidate mantissa for multiplexer 840. Multiplexer 840 selects mantissa and exponent values either derived from the extracted msb position in extract-MSB-position 815, or from preset values of mantissa=12 and exponent=0, according to the test in decision block 805. Multiplexer 840 assigns values to eMant with <6,5,1> precision and eExp with <4,4,0> precision, to be used in equalizer adaptation circuitry 900.

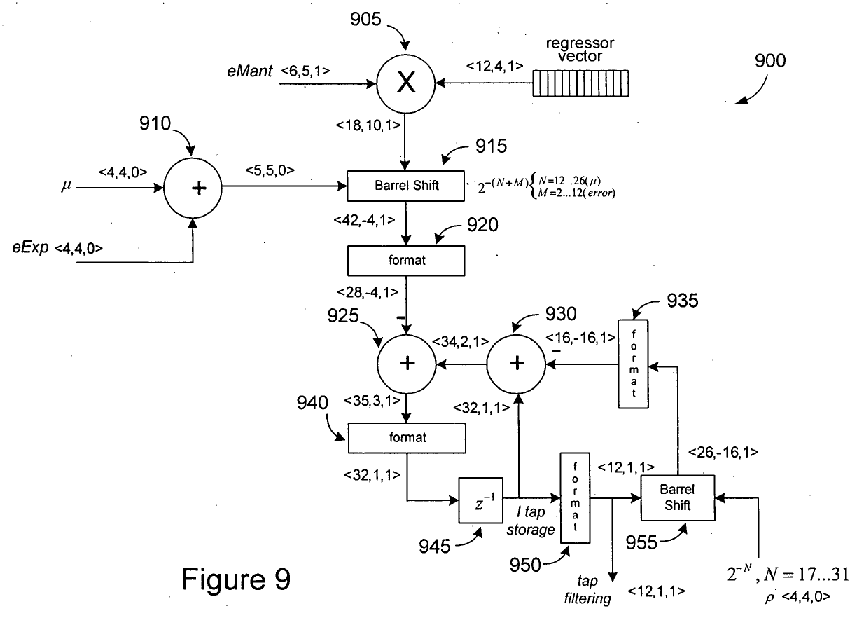

FIG. 9 illustrates equalizer adaptation circuitry 900 suitable for adjustment of real-valued adaptive filter coefficient, in accordance with the present invention. The <6,5,1> mantissa portion of the error term from error term preparation module 520 in FIG. 8 is multiplied with the <12,4,1> real-valued regressor sample in multiplier 905, producing an <18,10,1> result which is supplied to barrel shift 915. Barrel shift 915 applies a down shift by N+M bits, where M is between 2 and 12 and is determined directly from <4,4,0> eExp from error term preparation module 520 in FIG. 8, and N is determined from the stepsize value by setting N=(μ+11) for nonzero μ, thus accomplishing the shift range of 12 to 26. N and M are summed in adder 910, and the shift value is supplied to barrel shift 915. If μ is zero, the output of barrel shift 915 is zeroed. The total shift range of barrel shift 915 is therefore 14 to 38, and is accommodated with a <42,−4,1> output representation, which is truncated to <28,−4,1> in format 920. This <28,−4,1> output of format 920 is applied to the adder 925 which produces the updated coefficient.

In this adaptation circuitry, the coefficients are updated and stored at a higher precision than what is used in the filtering process of the adaptive filter; this prior art implementation detail helps save silicon area, compared to constraining the coefficient to the same bit width in filtering and adaptation processes, as studied in “Effects of finite bit precision on the constant modulus algorithm,” by L. Litwin et al., in Proceedings of the International Conference on Acoustics, Speech, and Signal Processing, Phoenix, Ariz., April, 1999.

The <35,3,1> updated coefficient produced by adder 925 is truncated to <32,1,1> in format 940 and stored in register 945. Format 950 truncates the stored coefficient to <12,1,1> and this result is used in the filtering process, and for leakage in barrel shift 955. Barrel shift 955 applies a shift value of (ρ+16) to barrel shift 955 for nonzero ρ, thus accomplishing the shift range of 17 to 31. If ρ is zero, the output of barrel shift 955 is zeroed. The output of barrel shift 955 extends to <26,−16,1> to accommodate the complete shift range possible, and is truncated to <16,−16,1> in format 935. This <16,−16,1> output of format 935 is summed with the <32,2,1> stored coefficient from register 945 in adder 930, and the <34,2,1> result is supplied to adder 925, which produces the next updated coefficient.

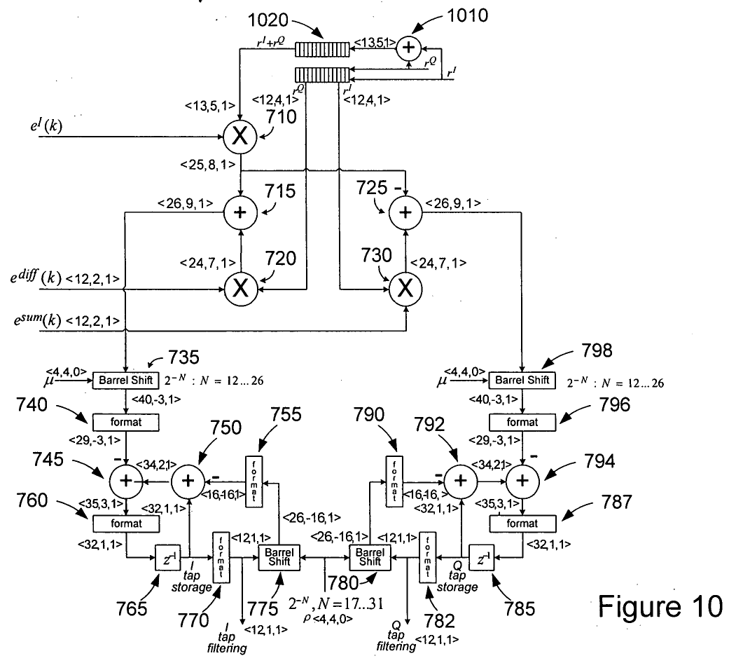

FIG. 10 shows alternative equalizer adaptation circuitry 1000 to equalizer adaptation circuitry 700. In FIG. 10, equalizer adaptation circuitry 1000 pre-calculates the sum of in-phase and quadrature-phase regressor samples in adder 1010 and stores the <13,5,1> result in vector 1020. This approach reduces the number of adders per each coefficient by one, so that it can be centrally done (common to all coefficients), but requires additional storage for vector 1020, while still eliminating a multiplier compared to standard prior art techniques.

One skilled in the art would understand that the equations described herein may include scaling, change of sign, or similar constant modifications that are not shown for simplicity. One skilled in the art would realize that such modifications can be readily determined or derived for the particular implementation. Thus, the described equations may be subject to such modifications, and are not limited to the exact forms presented herein.

As would be apparent to one skilled in the art, the various functions of equalization, signal combining, carrier correction, and automatic gain control may be implemented with circuit elements or may also be implemented in the digital domain as processing steps in a software program. Such software may be employed in, for example, a digital signal processor, micro-controller, or general-purpose computer.

The present invention can be embodied in the form of methods and apparatuses for practicing those methods. The present invention can also be embodied in the form of program code embodied in tangible media, such as floppy diskettes, CD-ROMs, hard drives, or any other machine-readable storage medium, wherein, when the program code is loaded into and executed by a machine, such as a computer, the machine becomes an apparatus for practicing the invention. The present invention can also be embodied in the form of program code, for example, whether stored in a storage medium, loaded into and/or executed by a machine, or transmitted over some transmission medium, such as over electrical wiring or cabling, through fiber optics, or via electromagnetic radiation, wherein, when the program code is loaded into and executed by a machine, such as a computer, the machine becomes an apparatus for practicing the invention. When implemented on a general-purpose processor, the program code segments combine with the processor to provide a unique device that operates analogously to specific logic circuits.

It will be further understood that various changes in the details, materials, and arrangements of the parts which have been described and illustrated in order to explain the nature of this invention may be made by those skilled in the art without departing from the principle and scope of the invention as expressed in the following claims.

What is claimed is:

1. A method for manipulating a complex-valued error term to reduce a number of required multiplication operations needed to adjust the coefficients of an adaptive filter, the coefficients updated according to a complex-valued error term derived in a communications receiver, the method comprising:
forming sums and differences of real-valued components of the complex-valued error term;
forming sums or differences of input samples to the adaptive filter; and
adjusting the coefficients of the adaptive filter with the sums and differences of the real-valued components of the complex-valued error term and the sums or differences of the input samples.

2. A method for manipulating an error term to adjust the coefficients of an adaptive filter, the method comprising:
splitting the error term into mantissa and exponent terms;
using the mantissa term to form an inner product with input data to the adaptive filter;
summing the exponent term with a stepsize term, and applying the sum as a shift down to the inner product, to form an update term; and
updating the adaptive filter coefficients based on said update term.
